(19) United States
(12) Patent Application Publication
(10) Pub. No.: US 2022/0270541 A1
(43) Pub. Date: Aug. 25, 2022

(54) DISPLAY APPARATUS AND LED MODULE THEREOF

(71) Applicant: AU Optronics Corporation, Hsin-Chu (TW)

(72) Inventors: Pei-Fen Lai, Hsin-Chu (TW); Hung-Chi Wang, Hsin-Chu (TW); Ya-Fang Chen, Hsin-Chu (TW); Chih-Hsiang Yang, Hsin-Chu (TW)

(21) Appl. No.: 17/401,357

(22) Filed: Aug. 13, 2021

(30) Foreign Application Priority Data
Feb. 24, 2021 (TW) 110106556

(51) Int. Cl. G09G 3/32; H01L 25/16; G06F 3/042; G06F 3/03; H04B 10/50

(52) U.S. Cl. CPC G09G 3/32; H01L 25/167; G06F 3/042; G06F 3/0308; H04B 10/502; G09G 2300/026; G09G 2370/18; G09G 2354/00; G09G 2360/14

(57) ABSTRACT

A display apparatus is disclosed. The display apparatus includes a LED module, a driving module and a control module. The driving module is coupled between the LED module and the control module. The LED module includes a plurality of package units. Each package unit includes a plurality of LEDs and at least one functional circuit. The driving module includes a conversion unit for receiving a first signal from the at least one functional circuit and converting it into a second signal. The control module controls the driving module to correspondingly change the operation of the LED module according to the second signal.

### BACKGROUND OF THE INVENTION

### 1. Field of the Invention

The invention relates to a display; in particular, to a display apparatus and a light-emitting diode (LED) module thereof.

### 2. Description of the Prior Art

With the rapid development of display technology, LED stitched displays using LED panel stitching technology to achieve super-large and special-shaped displays have gradually attracted attention in the market.

For example, as shown in FIG. 1, a LED stitched display 1 is formed by splicing a plurality of LED panels D1 to D9, and an infrared sensor SEN can be disposed anywhere in the LED stitched display 1 to receive an infrared control signal IR transmitted by a remote-control device CON to realize a remote-control function of controlling a part of or all the plurality of LED panels D1 to D9. However, the existing LED stitched display 1 fails to support the user to transmit the infrared control signal IR through the remote-control device CON to achieve the function of writing or drawing, resulting in limited types of functions provided and needs to be improved urgently.

Please also refer to FIG. 2. Since two adjacent LED panels (for example, an output terminal OUT1 of the LED panel D1 and an input terminal IN2 of the LED panel D2) in the existing LED stitched display 1 are connected to each other through a cable CAB and transmit a signal SIN in a daisy chain way. Therefore, when the overall stitching area of the LED stitched display 1 is larger, that is, the number of stitched LED panels is larger, the path length of the signal SIN needs to be transmitted becomes longer, resulting in more serious waveform distortion of the signal SIN.

For example, taking the LED stitched display 1 formed by stitching nine LED panels D1 to D9 in FIG. 1 as an example, when the infrared sensor SEN disposed on the LED panel D1 receives the infrared remote-control signal IR as shown in FIG. 3A, the infrared remote-control signal IR has no waveform distortion at this time.

Next, the infrared remote-control signal IR will be transmitted from the LED panel D1 to the LED panel D2, LED panel D3, . . . , and LED panel D9 in order. When the infrared remote-control signal IR is transmitted to the LED panel D5, as shown in FIG. 3B, the infrared remote-control signal IR has waveform distortion at this time; when the infrared remote-control signal IR is transmitted to the LED panel D9, as shown in FIG, 3C, the waveform distortion of the infrared remote-control signal IR becomes more serious at this time, resulting in the deviation and uneven brightness of the display screen of the entire LED stitched display 1, which needs to be improved urgently.

### SUMMARY OF THE INVENTION

Therefore, the invention provides a display apparatus and a LED module thereof to solve the above-mentioned problems of the prior arts.

A preferred embodiment of the invention is a display apparatus. In this embodiment, the display apparatus includes a LED module, a driving module and a control module. The driving module is coupled between the LED module and the control module. The LED module includes a plurality of package units. Each package unit includes a plurality of LEDs and at least one functional circuit. The driving module includes a conversion unit configured to receive a first signal from the at least one functional circuit and convert the first signal into a second signal. The control module is configured to control the driving module to correspondingly change the operation of the LED module according to the second signal.

In an embodiment, the at least one functional circuit is a photo detector (PD) for detecting a touch behavior and emitting the first signal.

In an embodiment, the at least one functional circuit is an infrared (IR) sensor for sensing an infrared signal and emitting the first signal.

In an embodiment, the infrared signal is emitted from a controller outside the LED module.

In an embodiment, the at least one functional circuit is an optical communication unit disposed at either side of the package unit for transmitting a display data signal through optical communication.

In an embodiment, the optical communication unit is a transmitter and/or a receiver.

In an embodiment, the optical communication unit includes a compensation unit for compensating a distortion of the display data signal.

In an embodiment, the conversion unit includes an automatic gain controller/a transimpedance amplifier, a bandpass filter, an analog-to-digital converter, a demodulator and a data sink; the first signal is processed by the automatic gain controller/the transimpedance amplifier, the bandpass filter, the analog-to-digital converter and the demodulator in order to be converted into the second signal and the second signal is transmitted to the control module through the data sink.

In an embodiment, the functional circuit is disposed on a first substrate, and the first substrate and the plurality of LEDs are all disposed on a second substrate.

In an embodiment, the functional circuit and the plurality of LEDs are connected to a third substrate respectively or the second substrate is connected to the third substrate.

Another preferred embodiment of the invention is a LED module. In this embodiment, the LED module is applied to a display apparatus. The display apparatus also includes a driving module and a control module, and the driving module is coupled between the LED module and the control module. The LED module includes a plurality of package units, and each package unit includes a plurality of LEDs and at least one functional circuit. When the at least one functional circuit transmits a first signal to the driving module, the driving module is configured to convert the first signal into a second signal, and the control module is configured to control the driving module to correspondingly change the operation of the LED module according to the second signal.

Compared to the prior art, the display apparatus of the invention is an LED stitched display, which can be equipped with an optical communication unit on either side of the LED module and can appropriately compensate the waveform distortion of the transmitted signal through a built-in compensation unit (e.g., a buffer). Therefore, even when the stitching area of the LED stitched display becomes lamer (that is, the number of stitched LED panels increases), the LED stitched display can still maintain the uniform brightness of the entire display screen, which can effectively improve the shortcoming of serious waveform distortion of signal due to longer signal transmission distance in the prior art. In addition, the LED stitched display of the invention can also support the user to perform the function of writing or drawing in a way of infrared remote-control or touch, thereby providing more diverse types of functions.

The advantage and spirit of the invention may be understood by the following detailed descriptions together with the appended drawings.

### BRIEF DESCRIPTION OF THE APPENDED DRAWINGS

FIG. 1 illustrates a schematic diagram of a conventional LED stitched display receiving an infrared control signal and transmitting it to each LED panel in order.

FIG. 2 illustrates a schematic diagram of connecting adjacent LED panels in a conventional LED stitched display through a cable and transmitting signals in a daisy chain way.

FIG. 3A to FIG. 3C illustrate schematic diagrams respectively showing that waveform distortion of the infrared remote-control signal in the conventional LED stitched display becomes serious with the increasing of the signal transmission distance.

FIG. 4 illustrates a functional block diagram of a display apparatus in a preferred embodiment of the invention.

FIG. 5 illustrates a schematic diagram of the package unit in FIG. 4 including a LED and a functional circuit.

FIG. 6 illustrates a schematic diagram showing that the package unit providing the optical communication function can be disposed at different positions around the LED module.

FIG. 7 illustrates a schematic diagram of a package unit including a transmitter (TX).

FIG. 8 illustrates a schematic diagram of a package unit including a receiver (RX).

FIG. 9 illustrates a schematic diagram of a package unit including a receiver (RX) and a package unit including a transmitter (TX) disposed adjacent to each other.

FIG. 10A to FIG. 10C illustrate schematic diagrams showing that the waveform distortion of the infrared remote-control signal in the LED stitched display of the invention will not become serious with the increasing of the signal transmission distance.

FIG. 11 illustrates a functional block diagram of the controller.

FIG. 12 to FIG. 14 illustrate schematic diagrams of package units using different package structures respectively.

FIG. 15 illustrates a schematic diagram of the LED stitched display of the invention realizing the function of writing or drawing in a way of remote-control or touch.

FIG. 16 illustrates a schematic diagram of the package units including different functional circuits being interlacedly stitched with each other in the invention.

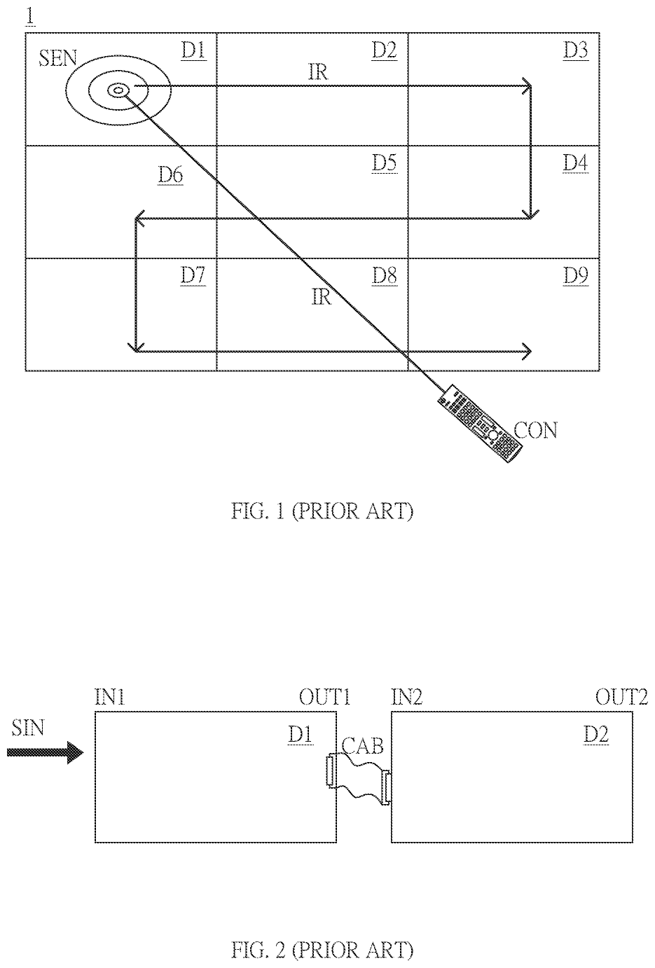

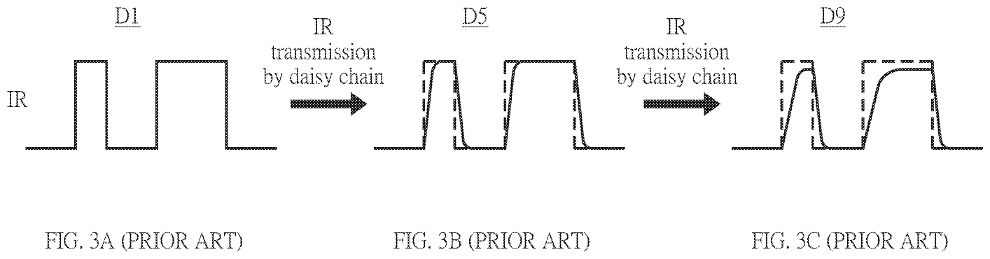

### DETAILED DESCRIPTION OF THE INVENTION

The following will clearly illustrate the spirit of the present disclosure with diagrams and detailed descriptions. Anyone with ordinary knowledge in the technical field who understands the embodiments of the present disclosure can change and modify them from the techniques taught in the present disclosure, and it does not depart from the spirit and scope of the present disclosure.

Regarding “first”, “second”, etc. used in this text, it does not specifically refer to order or sequence, nor is it used to limit the invention. It is only used to distinguish elements or operations described in the same technical terms.

Regarding the “electrical coupling” used in this disclosure, it can mean that two or more components directly make physical or electrical contact with each other, or make physical or electrical contact with each other indirectly, and “electrical coupling” can also refer to the mutual operation or action of two or more elements.

The terms “include”, “have”, “comprise”, etc. used in this disclosure are all open terms, which means including but not limited to.

Regarding the “and/or” used in this disclosure, it includes any or all combinations of the aforementioned things.

Regarding the directional terms used in this article, such as: up, down, left, right, front or back, etc., only refer to the directions of the attached drawings. Therefore, the directional terms used are used to illustrate but not to limit the case.

The terms “approximately” and “about” used in this disclosure are used to modify any amount or error that can be slightly changed, but such slight changes or errors will not change their essence.

Regarding the terms used in this disclosure, unless otherwise specified, each term usually has the usual meaning of each term used in this field, in the content disclosed here, and in the special content, Some terms used to describe the present disclosure will be discussed below or elsewhere in this specification to provide those skilled in the art with additional guidance on the description of the present disclosure.

A preferred embodiment of the invention is a display apparatus. In this embodiment, the display apparatus can be a LED stitched display formed by stitching a plurality of LED panels with each other, but not limited to this.

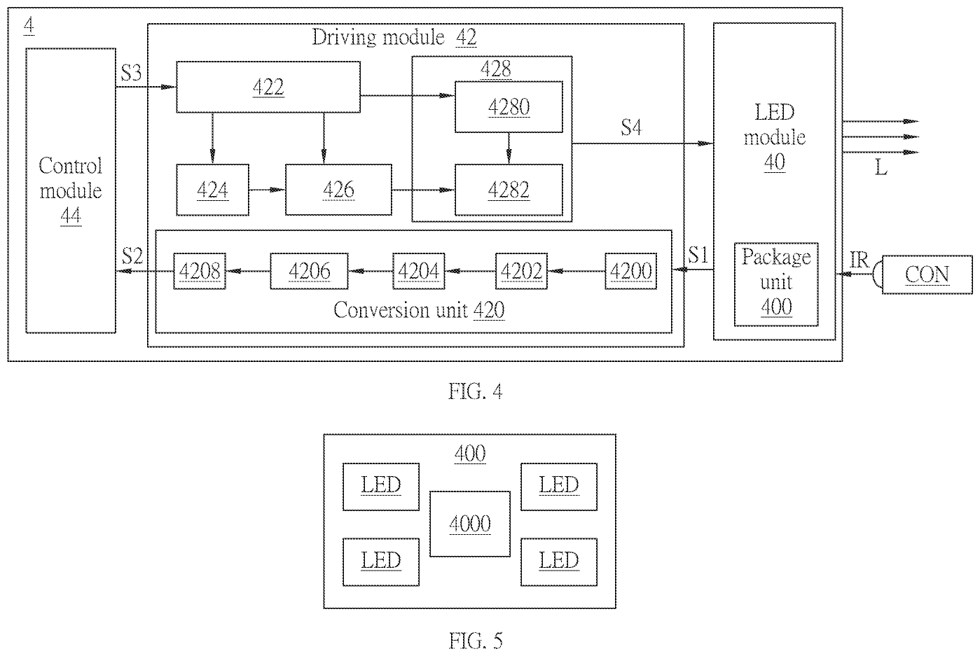

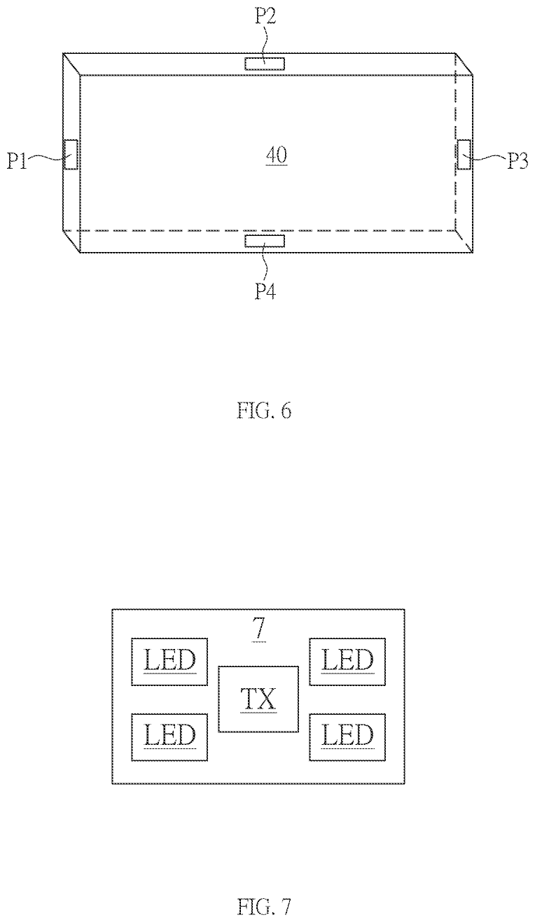

Please refer to FIG. 4. FIG. 4 illustrates a functional block diagram of the display apparatus in this embodiment. As shown in FIG. 4, the display apparatus 4 includes a LED module 40, a driving module 42 and a control module 44. The driving module 42 is coupled between the LED module 40 and the control module 44. The LED module 40 includes a plurality of package units 400. Each package unit 400 includes a plurality of light-emitting diodes LED and a functional circuit 4000 (as shown in FIG. 5).

The driving module 42 includes a conversion unit 420 for receiving a first signal S1 from the functional circuit 4000 in the package unit 400 and converting the first signal S1 into a second signal S2 and then outputting the second signal S2 to the control module 44. The control module 44 is used for transmitting a third signal S3 to the driving module 42 according to the second signal S2 to control the driving module 42 to transmit a fourth signal S4 correspondingly to change the operation of the LED module 40.

In practical applications, the functional circuit 4000 in the package unit 400 can be an infrared (IR) sensor for receiving an infrared remote-control signal IR transmitted by a controller CON and transmitting the first signal S1 to the driving module 42 accordingly, but not limited to this; the functional circuit 4000 in the package unit 400 can also be a photo detector (PD) for detecting a touch behavior and transmitting the first signal S1 accordingly, but not limited to this. The control module 44 can be a micro-controller unit (MCU) or a field programmable gate array (FPGA), but not limited to this.

In this embodiment, the conversion unit 420 in the driving module 42 can include an automatic gain control (AGC)/a transimpedance amplifier (TIA) 4200, a band-pass filter (BPF) 4202, an analog-to-digital converter (ADC) 4204, a demodulator 4206 and a data sink 4208 connected in series with each other. When the conversion unit 420 receives the first signal S1, the AGC/TIA 4200, the BPF 4202, the ADC 4204 and the demodulator 4206 will sequentially process the first signal S1 and convert the first signal S1 into the second signal S2 that can be received by the control module 44, and the second signal S2 is transmitted to the control module 44 through the data sink 4208.

In addition, the driving module 42 can further include a memory 422, a receiver 424, an analog-to-digital conversion and regulator 426 and a current control unit 428. The memory 422 is coupled to the control module 44, the receiver 424, the analog-to-digital conversion and regulator 426 and the current control unit 428 respectively. The receiver 424 is coupled to the memory 422 and the analog-to-digital converter and regulator 426 respectively. The analog-to-digital converter and regulator 426 is coupled to the memory 422, the receiver 424 and the current control unit 428 respectively. The current control unit 42.8 is coupled to the memory 422, the analog-to-digital converter and regulator 426 and the LED module 40 respectively.

The current control unit 428 includes a pulse-width modulation (PWM) signal generator 4280 and a current sink/source 4282. When the driving module 42 receives the third signal S3 from the control module 44, the memory 422 is used to store the third signal S3 and the third signal S3 is processed by the receiver 424, the analog-digital conversion and regulator 426, the PWM signal generator 4280 and the current sink/source 4282 to output a fourth signal S4 to the LED module 40 to control a LED current flowing through the plurality of light-emitting diodes LED, thereby controlling the visible lights L emitted by the plurality of light-emitting diodes LED.

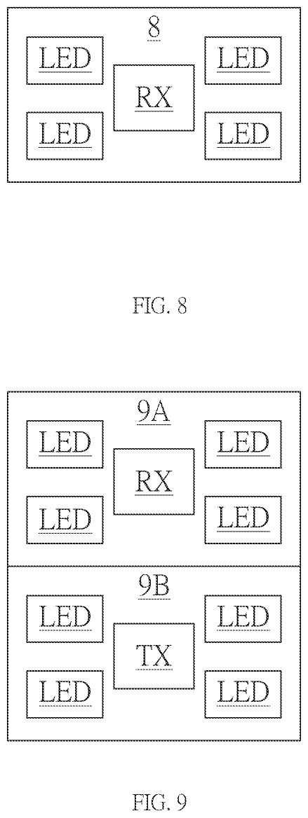

In one embodiment, as shown in FIG. 6, the positions P1˜P4 on either side of the LED module 40 can be used to dispose the package unit 400 including an optical communication unit to transmit the display data signal through optical communication. For example, the package unit 7 in FIG, 7 includes the transmitter TX; the package unit 8 in FIG. 8 includes the receiver RX; the package unit 9A including the receiver RX and the package unit 9B including the transmitter TX are disposed adjacently in FIG. 9, but not limited to this.

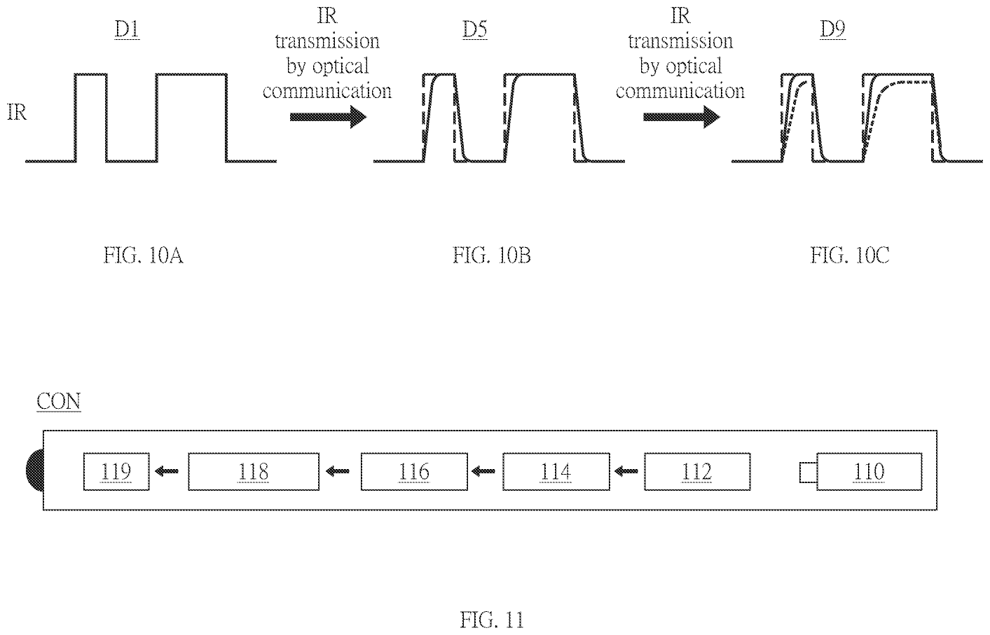

In practical applications, the optical communication unit in the above-mentioned package unit can further include a compensation unit (not shown), such as a buffer, which is used for compensating waveform distortion of the transmitted signal. Thereby, when the infrared remote-control signal IR is transmitted from the LED panel D1 to the LED panel D9 in order through optical communication and the waveform distortion of the infrared remote-control signal IR is timely compensated, as shown in FIG. 10A to FIG. 10C, even if the infrared remote-control signal IR is transmitted to the LED panel D9, the waveform distortion of the infrared remote-control signal IR is still within an acceptable range and will not become more serious, so as to effectively improve the display deviation and uneven brightness of the conventional LED stitched display.

Next, please refer to FIG. 11. As shown in FIG. 11, the controller CON used to emit the infrared remote-control signal can include a power supply 110 and a signal controller 112 connected in series with each other, an AGC 114, and a DAC 116, a modulator 118 and an IR transmitter 119.

The power supply 110 is used to provide power required for the operation of the controller CON. The control signal transmitted by the signal controller 112 is processed into an infrared remote-control signal by the AGC 114, the DAC 116 and the modulator 118 in order, and the infrared remote-control signal is output through the IR transmitter 119, but not limited to this.

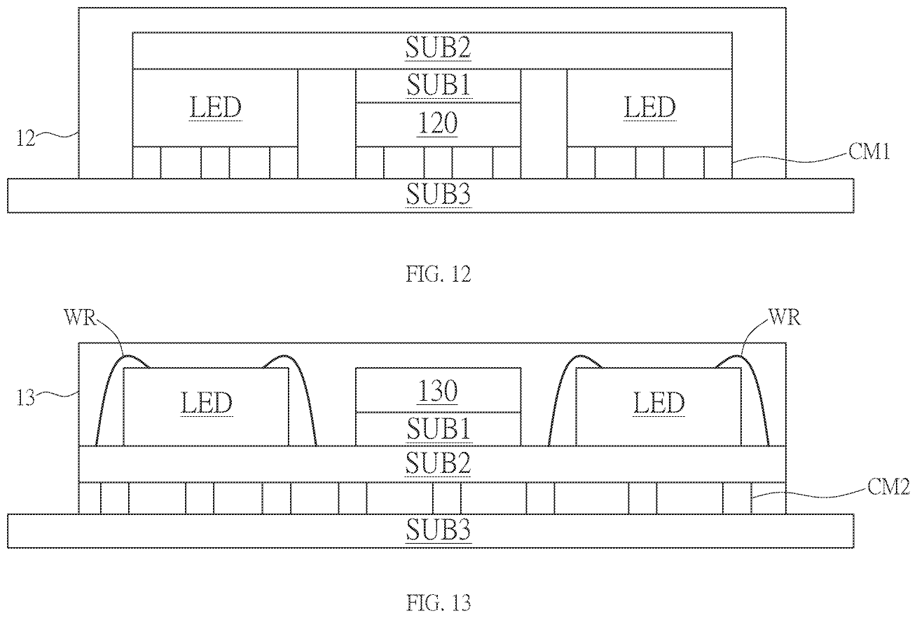

Please refer to FIG. 12 to FIG. 14. FIG. 12 to FIG. 14 illustrate schematic diagrams of the package units 12 to 14 using different package structures respectively.

As shown in FIG. 12, the package unit 12 is disposed on a substrate SUB3. The package unit 12 includes substrates SUB1 to SUB2, a light-emitting diode LED, a functional circuit 120 and a connection unit CM1. The light-emitting diode LED is disposed on the substrate SUB2 and connected to the substrate SUB3 through the connection unit CM1. The functional circuit 120 is disposed on the substrate SUB1 and the substrate SUB1 is disposed on the substrate SUB2. The functional circuit 120 is also connected to the substrate SUB3 through the connection unit CM1.

As shown in FIG. 13, the package unit 13 is disposed on a substrate SUB3. The package unit 13 includes substrates SUB1 to SUB2, a light-emitting diode LED, a functional circuit 130 and a connection unit CM2. The light-emitting diode LED is disposed on the substrate SUB2 and connected to the substrate SUB2 through bonding wires WR. The functional circuit 130 is disposed on the substrate SUB1 and the substrate SUB1 is disposed on the substrate SUB2. The substrate SUB2 is connected to the substrate SUB3 through the connection unit CM2.

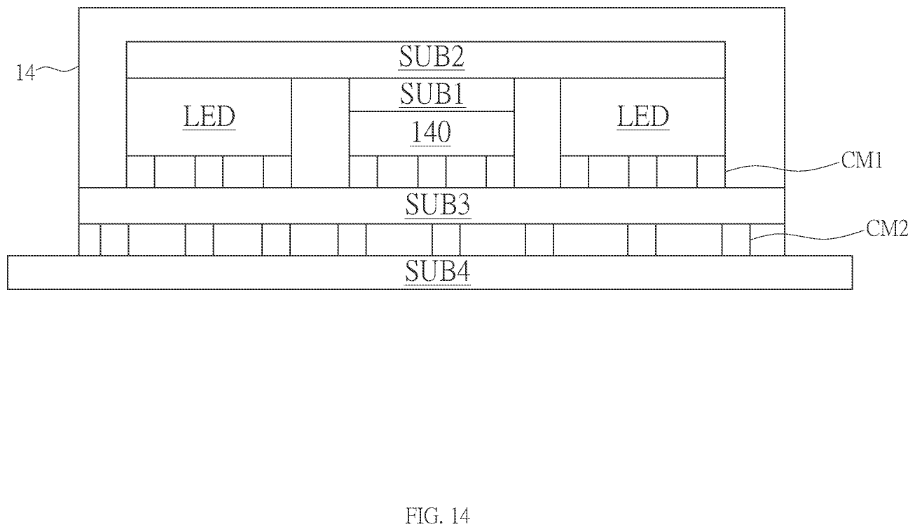

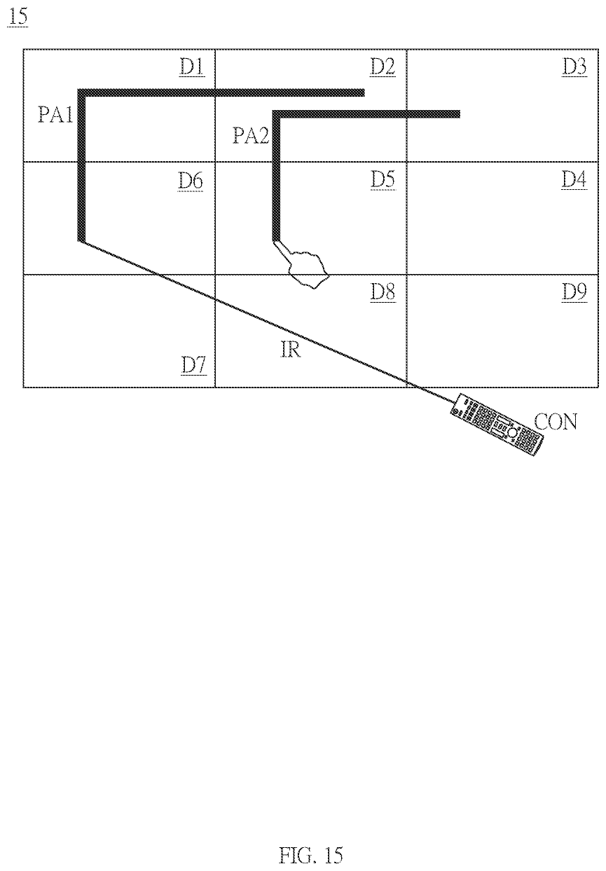

As shown in FIG. 14, the package unit 14 is disposed on a substrate SUB4. The package unit 14 includes substrates SUB1 to SUB3, a light-emitting diode LED, a functional circuit 140 and connection units CM1 and CM2. The light-emitting diode LED is disposed on the substrate SUB2 and connected to the substrate SUBS through the connection unit CM1. The functional circuit 140 is disposed on the substrate SUB1 and the substrate SUB1 is disposed on the substrate SUB2. The functional circuit 140 is also connected to the substrate SUB3 through the connection unit CM1. The substrate SUBS is connected to the substrate SUB4 through the connection unit CM2.

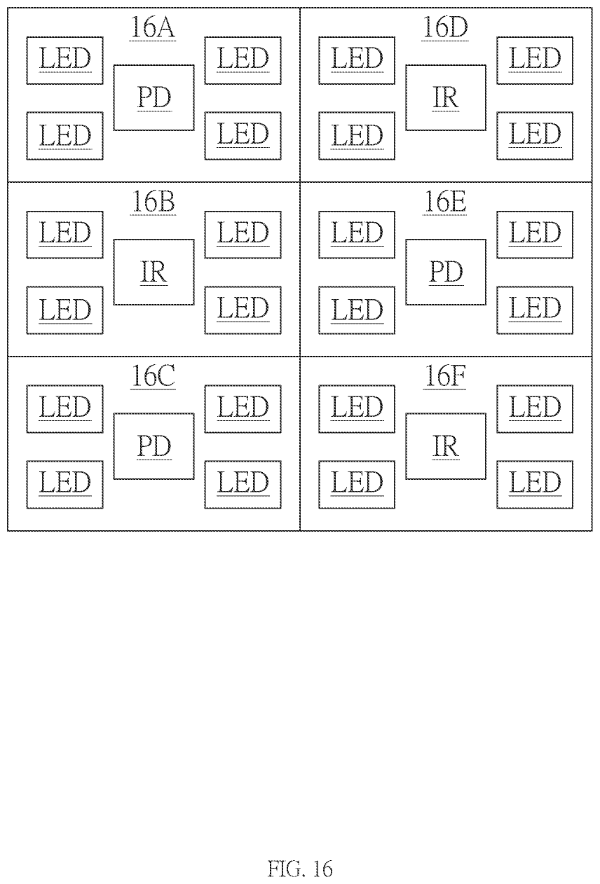

In practical applications, as shown in FIG. 15, the LED stitched display 15 of the invention can realize functions of writing or drawing (e.g., line segments PA1 and PA2) by receiving the infrared remote-control signal IR transmitted by the controller CON or detecting the touch of a finger FIN. For example, as shown in FIG. 16, the package units 16A, 16C and 16E including a photodetector PD and the package units 16B, 16D and 16F including an infrared sensor IR can be interlacedly stitched with each other.

Among them, the photodetector PD can determine whether there is a touch behavior based on whether the visible light received by the photodetector PD changes. If it is determined that the touch behavior occurs, the light-emitting state of each LED panel can be correspondingly controlled according to the movement track of the touch position, so as to realize the function of writing or drawing on the LED stitched display. Similarly, the infrared sensor IR can also determine whether a remote-control behavior occurs according to whether the infrared sensor IR receives the infrared remote-control signal. If it is determined that the remote-control behavior occurs, the light-emitting state of each LED panel can be correspondingly controlled according to the movement track of the remote-control signal, so as to realize the function of writing or drawing on the LED stitched display.

Compared to the prior art, the display apparatus of the invention is an LED stitched display, which can be equipped with an optical communication unit on either side of the LED module and can appropriately compensate the waveform distortion of the transmitted signal through a built-in compensation unit (e.g., a buffer). Therefore, even when the stitching area of the LED stitched display becomes larger (that is, the number of stitched LED panels increases), the LED stitched display can still maintain the uniform brightness of the entire display screen, which can effectively improve the shortcoming of serious waveform distortion of signal due to longer signal transmission distance in the prior art. In addition, the LED stitched display of the invention can also support the user to perform the function of writing or drawing in a way of infrared remote-control or touch, thereby providing more diverse types of functions.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

1. A display apparatus, comprising:
a light-emitting diode (LED) module, comprising a plurality of package units, wherein each package unit comprises a plurality of LEDs and at least one functional circuit;
a driving module, coupled to the LED module, comprising a conversion unit configured to receive a first signal from the at least one functional circuit and convert the first signal into a second signal; and
a control module, coupled to the driving module, configured to control the driving module to correspondingly change an operation of the LED module according to the second signal;
wherein the at least one functional circuit is an optical communication unit disposed at either side of the package unit for transmitting a display data signal through optical communication and the optical communication unit comprises a buffer for compensating a waveform distortion of the display data signal.

2. The display apparatus of claim 1, wherein the at least one functional circuit is a photo detector (PD) for detecting a touch behavior and emitting the first signal.

3. The display apparatus of claim 1, wherein the at least one functional circuit is an infrared (IR) sensor for transmitting an infrared signal and emitting the first signal.

4. The display apparatus of claim 3, wherein the infrared signal is emitted from a controller outside the LED module.

5. (canceled)

6. The display apparatus of claim 1, wherein the optical communication unit is a transmitter and/or a receiver.

7. (canceled)

8. The display apparatus of claim 1, wherein the conversion unit comprises an automatic gain controller/a transimpedance amplifier, a bandpass filter, an analog-to-digital converter, a demodulator and a data sink; the first signal is processed by the automatic gain controller/the transimpedance amplifier, the bandpass filter, the analog-to-digital converter and the demodulator in order to be converted into the second signal and the second signal is transmitted to the control module through the data sink.

9. The display apparatus of claim 1, wherein the functional circuit is disposed on a first substrate, and the first substrate and the plurality of LEDs are all disposed on a second substrate.

10. The display apparatus of claim 9, wherein the functional circuit and the plurality of LEDs are connected to a third substrate respectively or the second substrate is connected to the third substrate.

11. A light-emitting diode (LED) module applied to a display apparatus, the display apparatus further comprising a driving module and a control module, and the driving module being coupled between the LED module and the control module, the LED module comprising:
a plurality of package units, wherein each package unit comprises a plurality of LEDs and at least one functional circuit, when the at least one functional circuit transmits a first signal to the driving module, the driving module is configured to convert the first signal into a second signal, and the control module is configured to control the driving module to correspondingly change the operation of the LED module according to the second signal;
wherein the at least one functional circuit is an optical communication unit disposed at either side of the package unit for transmitting a signal through optical communication, the optical communication unit comprises a buffer for compensating a waveform distortion of the display data signal.

12. The LED module of claim 11, wherein the at least one functional circuit is a photo detector (PD) for detecting a touch behavior and emitting the first signal.

13. The LED module of claim 11, wherein the at least one functional circuit is an infrared (IR) receiver for receiving an infrared signal and emitting the first signal.

14. The LED module of claim 13, wherein the infrared signal is emitted from a controller outside the LED module.

15. (canceled)

16. The LED module of claim 11, wherein the optical communication unit is a transmitter and/or a receiver.

17. (canceled)

18. The LED module of claim 11, wherein the conversion unit comprises an automatic gain controller/a transimpedance amplifier, a bandpass filter, an analog-to-digital converter, a demodulator and a data sink; the first signal is processed by the automatic gain controller/the transimpedance amplifier, the bandpass filter, the analog-to-digital converter and the demodulator in order to be converted into the second signal and the second signal is transmitted to the control module through the data sink.

19. The LED module of claim 11, wherein the functional circuit is disposed on a first substrate, and the first substrate and the plurality of LEDs are all disposed on a second substrate.

20. The LED module of claim 19, wherein the functional circuit and the plurality of LEDs are connected to a third substrate respectively or the second substrate is connected to the third substrate.
